(19) United States
(12) Patent Application Publication
(10) Pub. No.: US 2025/0297121 A1
(43) Pub. Date: Sep. 25, 2025

(54) PROCESS OF FORMULATING GRAPHENE INKS WITH HIGH ELECTRONIC CONDUCTIVITY AND TUNABLE ATOMIC DEFECTS

(71) Applicant: Kansas State University Research Foundation, Manhattan, KS (US)

(72) Inventors: Suprem R. Das, Manhattan, KS (US); Rajavel Krishnamoorthy, Manhattan, KS (US); Thiba Nagaraja, Manhattan, KS (US)

(21) Appl. No.: 18/863,757

(22) PCT Filed: May 10, 2023
(86) PCT No.: PCT/US2023/066828

§ 371 Date: Nov. 7, 2024

Related U.S. Application Data
(60) Provisional application No. 63/340,126, filed on May 10, 2022.

(51) Int. Cl. C09D 11/52; C01B 32/19; C01B 32/196; C01B 32/21; C09D 11/033; C09D 11/037; G01N 27/04

(52) U.S. Cl. CPC C09D 11/52; C01B 32/19; C01B 32/196; C01B 32/21; C09D 11/033; C09D 11/037; G01N 27/04; C01B 2204/04; C01B 2204/22; C01B 2204/32; C01P 2006/40

(57) ABSTRACT

Electrically conductive graphene inks and processes for exfoliating graphite to form few-layered graphene, especially graphene with average thickness of (20) atomic layers or less, or in some embodiments (10) atomic layers or less, that can be used in manufacture of graphene inks are provided. The few-layered graphene ink can be used to fabricate electronic and electrochemical devices, such as sensors.

### CROSS-REFERENCE TO RELATED APPLICATION

This application claims the benefit of U.S. Provisional Patent Application No. 63/340,126, filed May 10, 2022, which is incorporated by reference herein in its entirety.

### STATEMENT REGARDING FEDERALLY SPONSORED RESEARCH

This invention was made with government support under Grant No. 1935676 awarded by the National Science Foundation (NSF). The government has certain rights in the invention.

### BACKGROUND OF THE INVENTION

### Field of the Invention

Embodiments of the present invention are directed toward highly stable graphene inks, and processes for formulating the same, that are electrically conductive and can be used in the fabrication of electronic devices, such as electronic sensors.

### Description of the Prior Art

The use of graphene in electronic devices such as micro-scale energy storage devices (e.g., micro-supercapacitors (micro-SCs)), micro-batteries, and other microelectronic devices has garnered much interest due to graphene's electrical conductivity characteristics. However, exploiting these desirable characteristics of graphene production in a large scale and scalable platform while controlling its thickness (in terms of number of atomic layers) has proven to be challenging due to inter atomic layer resistance (van der Waals interactions between atomic layers), inhomogeneity in flake size and size distribution, and their structural quality. Moreover, additive manufacturing techniques such as screen printing, inkjet printing, and 3D printing have also attracted much attention due to their adaptability to large-scale manufacturing processes but necessitates formulations of making conductive ink from above produced graphene.

Graphene can be manufactured in a number of ways. One exemplary mode of manufacturing is described in U.S. Pat. No. 10,800,939, which is directed toward a method for preparing concentrated graphene ink compositions. The method involves exfoliating a graphene source material with a medium comprising an organic solvent at least partially miscible with water and a cellulosic polymer dispersing or stabilizing agent at least partially soluble in such an organic solvent. At least a portion of such an exfoliated graphene medium is contacted with a hydrophobic fluid component, and the graphene medium is hydrated to concentrate exfoliated graphene in such a hydrophobic fluid component.

U.S. Pat. No. 9,440,857 is directed toward a method of producing pristine graphene particles through a one-step, gas-phase, catalyst-free detonation of a mixture of one or more carbon-containing compounds hydrocarbon compounds and one or more oxidizing agents. The detonation reaction occurs very quickly and at relatively high temperature, greater than 3000 K, to generate graphene nanosheets that can be recovered from the reaction vessel, such as in the form of an aerosol. The graphene nanosheets may be stacked in single, double, or triple layers, for example, and may have an average particle size of between about 35 to about 250 nm.

U.S. Patent Application Publication No. 2017/0081537 is directed toward a rapid, scalable methodology for graphene dispersion and concentration with a polymer-organic solvent medium, as can be utilized without centrifugation, to enhance graphene concentration.

International Patent Application Publication No. WO 2014/210584 is directed toward a dispersion of nanoplatelet graphene-like material, such as graphene nanoplatelets, in a solid or liquid dispersion media wherein the nanoplatelet graphene-like material is dispersed substantially uniformly in the dispersion media with a graphene-like material dispersant. Such dispersions may be used to prepare articles by three-dimensional (3D) printing, as well as to provide electrically conductive inks and coatings, chemical sensors and biosensors, electrodes, energy storage devices, solar cells, etc. Liquid dispersions may be prepared, for example, by sonication of solutions of graphite flakes, dispersant, and liquid dispersion media, while solid dispersions may be prepared, for example, by combining the melted polymer with the liquid dispersion, dissolving the solid polymer in a miscible solvent and then blending with the liquid dispersion, dissolving the solid polymer in the liquid dispersion, or polymerizing one or more monomers in the liquid dispersion to form the solid polymer.

### SUMMARY OF THE INVENTION

According to one embodiment of the present invention there is provided a method of forming a graphene ink comprising forming a mixture comprising graphite powder and an exfoliating agent for the graphite powder dispersed within a liquid dispersant. Energy is added to the mixture thereby causing at least a portion of the graphite powder to exfoliate into few-layered graphene particles comprising less than 20 atomic layers. The exfoliated graphene particles are encapsulated by the exfoliating agent. At least a portion of the encapsulated graphene particles are separated from the mixture and then dispersed within a liquid vehicle system thereby forming the graphene ink.

According to another embodiment there is provided an ink composition comprising a quantity of few-layered graphene particles encapsulated within an exfoliating agent.

According to yet another embodiment there is provided an electronic or electrochemical device comprising one or more traces printed with a graphene ink as described herein.

### BRIEF DESCRIPTION OF THE DRAWINGS

FIG. 1 is a flow chart of a process for producing graphene particles from graphite;

FIG. 2 is a schematic illustration of a sensor created from a graphene ink made in accordance with the present invention.

FIG. 3A is a transmission electron microscopy (TEM) image of a graphene flake prepared according to one embodiment of the present invention;

FIG. 3B is a high-resolution TEM (HR-TEM) of a graphene flake prepared according to one embodiment of the present invention;

FIG. 3C is an atomic force microscopy (AFM) image of a graphene flake prepared according to one embodiment of the present invention; and

FIG. 3D is a graph showing the average thickness of a quantity of graphene flakes prepared according to one embodiment of the present invention.

### DETAILED DESCRIPTION OF THE PREFERRED EMBODIMENT

In certain embodiments, the manufacture of graphene ink comprises the provision of graphene particles, especially pristine or nearly pristine graphene flake. In order to achieve desired electronic characteristics, a graphitic material is exfoliated into few-layered graphene via a controlled exfoliation process. As used herein, “few-layered graphene” refers to graphene comprising 20 or fewer atomic layers (e.g., 15 or less, or 10 or less). In one or more embodiments, the graphene utilized comprises 2 to 20 atomic layers.

The graphene particles prepared according to embodiments described herein may have some variability in thickness among the individual particles. However, in certain embodiments, the ink compositions may utilize a quantity of few-layered graphene particles having an average thickness of 20 or fewer atomic layers, 15 or fewer atomic layers, or 10 or fewer atomic layers. In certain embodiments, the ink compositions may utilize a quantity of few-layered graphene particles having an average thickness of 4 to 20 atomic layers, or 5 to 10 atomic layers. In certain embodiments, the quantity of few-layered graphene particles may have an average thickness of less than 10 atomic layers. As used herein, “average thickness” refers to the mean average of the number of atomic layers of at least 20 randomly selected particles from the quantity of graphene particles.

The graphene particles may generally range from about 100 nanometers to about 1.3 micrometers in size (based on the largest lateral dimension). In one of more embodiments, the quantity of graphene particles may be in the form of flakes having a mean average lateral dimension (D50) of about 200 nanometers to about 300 nanometers.

Controlled exfoliated synthesis of few-layered graphene can be achieved by number of process steps and/or formulations. It has been discovered that the exfoliation process can allow for the production of graphene with tunable atomic defects. These defects can include structural defects like vacancies, edge-defects, carbon adatoms, and Stone-Wales defects. The exfoliated graphene can be used to produce a series of low resistive graphene nano-inks. This graphene nano-ink making technology is scalable facilitating mass production of inks suitable for ubiquitous applications including but not limited to printed electronic and electrochemical devices, energy devices, chemical/biological sensors, conductive coatings for passivation, functional devices, and electromagnetic interference (EMI) shielding. The conductive graphene inks can also be used for transparent conducting electrodes (TCEs). The outstanding quality of graphene inks can, furthermore, provide a strong platform for building additive manufacturing technology such as graphene-based nanocomposites.

The synthesized graphene inks produced via these processes can exhibit low resistance (possibly due to substantial reduction of flake resistance and/or inter-flake resistance and/or a combination, while keeping the average layer thickness about 2 to about 20 layers, or about 10 layers in the ink). This allows for the manufacture of highly conductive inks suitable for printed electronics applications. These processes can also be well controlled so that the structural features of the graphene can be tuned, such as the layer thickness, level of defects present, functional moieties, etc. as compared to existing graphene ink technologies.

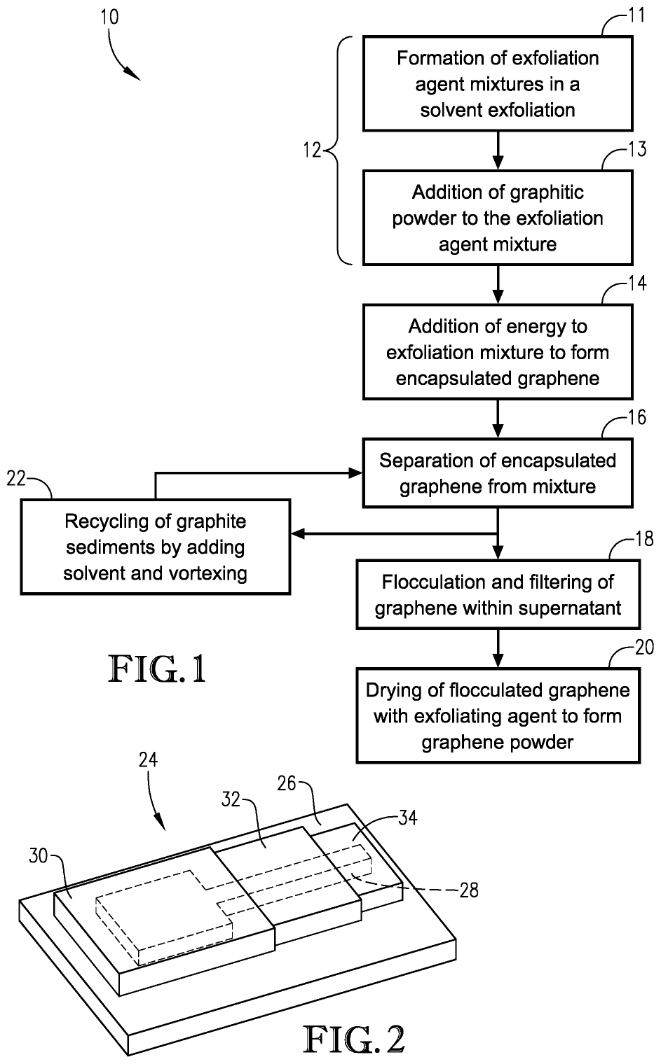

FIG. 1 depicts an exemplary process 10 for producing graphene that can be used in the manufacture of graphene inks. In one or more embodiments, a mixture is formed (step 12) comprising a graphite powder and an exfoliating agent for the graphite powder dispersed within a liquid dispersant. First, the exfoliation agent is mixed with the liquid dispersant (e.g., solvent) (step 11). Next, the graphite powder is added to the exfoliation agent mixture. In certain embodiments the exfoliating agent comprises ethyl cellulose, nitrocellulose, carboxymethylcellulose, or mixtures thereof. In preferred embodiments the exfoliating agent is present within the mixture in an amount of at least 0.1%, at least 0.2%, at least 0.3%, at least 0.4%, or at least 0.5% by weight/volume and/or not more than 5%, not more than 4%, not more than 3%, not more than 2%, or not more than 1% by weight/volume.

In certain embodiments, the liquid dispersant can comprise an alcohol, such as ethanol, water, ethanol and terpineol, toluene, or any other suitable dispersant for the exfoliating agent and graphite powder. In preferred embodiments, the graphite powder is present within the mixture in an amount of at least 1%, at least 2%, at least 3%, at least 4% or at least 5% by weight/volume, and/or not more than 20%, not more than 15%, or not more than 10% by weight/volume.

Next, energy is added (step 14) to the mixture thereby causing at least a portion of the graphite powder to exfoliate into few-layered graphene particles comprising less than 20, less than 15, or less than 10 atomic layers. The resulting exfoliated graphene particles are at least partially encapsulated by the exfoliating agent. In certain embodiments, the energy added to the mixture is sonic energy provided, for example, by one or more ultrasonic probes or wave generators. Additionally, or alternatively, a microfluidizer and/or shear mixer may also be used. In preferred embodiments, the energy is added for a period of time of at least 1 hr, at least 2 hr, at least 4 hr, or at least 6 hr and/or less than 14 hr, less than 12 hr, less than 10 hr, or less than 8 hr.

At least a portion of the encapsulated graphene particles are separated (step 16) from the mixture. In one or more embodiments, the separating step can comprise extracting the encapsulated graphene particles from the mixture by centrifuging the mixture and recovering a supernatant containing the encapsulated graphene particles. In preferred embodiments, the centrifuge is operated at a speed of at least 2000 rpm, at least 3,000 rpm, at least 4,000 rpm, or at least 5,000 rpm and/or less than 19,000 rpm, less than 10,000 rpm, less than 9,000 rpm, less than 8,000 rpm, or less than 7,500 rpm.

A flocculating agent can then be added (step 18) to the recovered supernatant thereby causing the encapsulated graphene particles to flocculate. In preferred embodiments, the flocculating agent is added to the mixture in an amount of about 1 mg/mL to about 50 mg/mL, or about 20 mg/mL to about 40 mg/mL. The flocculated graphene particles can then be recovered by filtering the supernatant. In certain embodiments, the flocculating agent comprises a salt such as sodium chloride. The recovered graphene particles can then be dried (step 20) to form a powder comprising the encapsulated graphene particles. In addition, any sediments not recovered in the supernatant can be recycled to the exfoliation and separation processes (step 22) in order to improve overall process yields. In certain embodiments, the sediments can be recycled through these processes one, two, three, four, five, or six times.

The encapsulated graphene particles then can be used to form a graphene ink. The graphene ink can be formulated for printing according to any conventional technique, such as digital or drop-on-demand (DoD) printing, inkjet printing, micro plotter printing, screen printing, or flexographic printing. In one or more embodiments, the encapsulated graphene particles are dispersed within a liquid vehicle system to form the graphene ink. In certain embodiments, the liquid vehicle system comprises one or more ketones, one or more alcohols, or a mixture of one or more ketones and alcohols. In a preferred embodiment, the liquid vehicle comprises cyclohexanone and terpineol. Other organic solvents having relatively high boiling points may also be used. The encapsulated graphene particles may be present within the ink in an amount of from about 5 wt. % to about 85 wt. % and will generally depend upon the type of printing process intended for the ink. For example, in some embodiments, the encapsulated graphene particles are present within the ink in an amount of about 5 wt. % to about 20 wt. %, or about 10 wt. % to about 15 wt. %. In some other embodiments, the encapsulated graphene particles are present within the ink in an amount of about 50 wt. % to about 85 wt. %, or about 60 wt. % to about 75 wt. %. In certain embodiments, the ink has a viscosity at 25° C. of from 10 to 500 cP. For example, for ink-jet ink, the ink has a viscosity at 25° C. of from 10 to 50 cP. For microplotter ink, the ink has a viscosity at 25° C. of from 50 to 300 cP. For screen printing ink, the ink has a viscosity at 25° C. of from 200 to 500 cP.

In one or more embodiments, the encapsulated graphene particles remain stably suspended within the ink for a period of at least 3 months, at least 6 months, at least 9 months, or at least one year. As used herein, “stably suspended” means that fewer than 10%, 7.5%, or 5% by weight of the graphene particles present within the ink precipitate out of or settle to the bottom of the ink composition. To the extent that any such graphene particles do settle, such particles are readily resuspended within the ink via gentle shaking or stirring or sonication (e.g., for about 10 to 15 minutes) of the ink for a period of less than 1 min, less than 30 sec., or less than 15 sec.

The graphene ink can be utilized in many applications such as coatings, composite materials, supercapacitors, chemical sensors, biosensors, and mechanical sensors, strain sensors, tactile sensors, transparent conducting electrodes. It can be used in a variety of ways, such as spin coating, dip coating, roll-to-roll manufacturing, etc., but is highly suitable for printed electronics. The ink can be tailored with polymers for a wide variety of composite inks. The ink can be tailored with other nanoparticles, nanotubes, and nanowires for numerous composite inks.

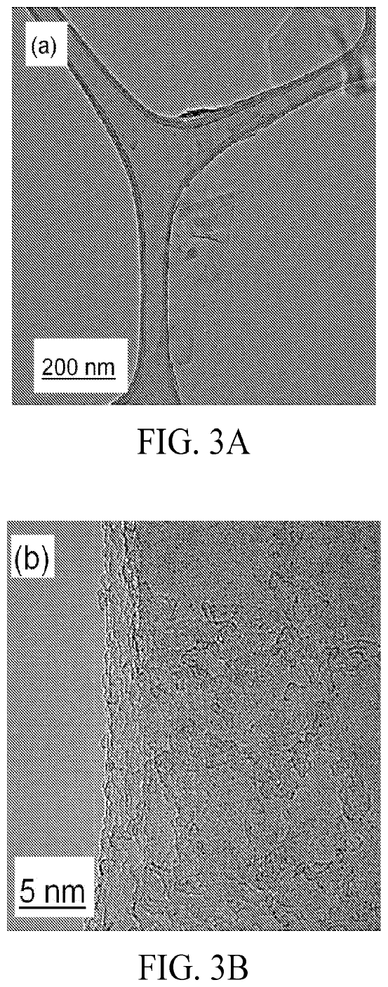

In one or more embodiments, electronic or electrochemical devices can be manufactured comprising one or more traces printed with a graphene ink as described herein. Particularly, the sensor comprises a phosphate sensor operable to detect phosphate ions present within a sample. Turning to FIG. 2, a phosphate sensor 24 is depicted that comprises a substrate 26 upon which a graphene ink trace 28 has been printed. The sensor 24 further comprises an ion-selective layer 30 applied over at least a portion of the one or more traces 28 printed with the graphene ink. In certain embodiments, the sensor 24 may further comprise an insulating layer 32 encapsulating at least a portion of the one or more traces 28 and/or a metal layer 34 (e.g., silver) for connecting to external circuitry. The insulating layer 32 and/or metal layer 34 may be printed onto the substrate 26. In certain embodiments, the ion selective layer 30 comprises a cerium acetylacetonate complex. The sensor is configured such that it is capable of discriminating between phosphate ions and nitrate ions, as the potentiometric response of the sensor is different for phosphate sensing that interfering nitrate ions at similar concentrations.

During sensor construction, after printing of the ink trace upon the substrate, the substrate and ink can be annealed in order to decompose and volatilize at least a portion of the exfoliating agent (e.g., ethyl cellulose) binding the graphene flakes. The annealing process may include rapid thermal annealing, photonic annealing, photonic curing, laser annealing, and the like. As the exfoliating agent can exhibit electrically insulative properties, the above treatments and subsequent removal of the exfoliating agent serve to improve the overall conductivity of the graphene ink. In certain embodiments, the heat treatment can occur by heating the substrate bearing the ink trace within an oven at a temperature of from 300° C. to 375° C. After printing and the volatilization of the embedded exfoliating agent in the printed layer ion-selective layer can be applied to form the sensor.

### EXAMPLES

The following examples describe methods of exfoliating graphene from graphite and formation of inks with the exfoliated graphene. It is to be understood, however, that these examples are provided by way of illustration and nothing therein should be taken as a limitation upon the overall scope of the invention.

The ink synthesis method is described with respect to the following steps, with each step comprising a series of sub-steps:

Step—1. Liquid Phase Exfoliation of Graphene from Graphite Via Ultrasonication
(a) The exfoliation agent, ethyl cellulose (from Sigma Aldrich, catalog #433837), (1 g) was initially mixed with 200 mL of ethanol in 250 ml beaker by 5-minute probe sonication with 100% amplitude (corresponding to 500 watt power) at 5 sec pulse and 5 sec pause mode.
(b) To the above mixture, 10 g of high purity graphite powder (from Sigma Aldrich, catalog #808113) was added.
(c) The layer separation process was initiated by placing the above mixture into the horn ultrasonicator in an ice-cold bath (to prevent evaporation of solvents and also overheating of probes) at 100% amplitude with 5 sec pulse and 5 sec pause for about 6 hours. Ice cubes were changed at 2 h intervals during the exfoliation process.

### Step—2. Separation of Few-Layer Graphene

(a) During probe sonication, graphene flakes were exfoliated from the graphite, which are encapsulated by ethyl cellulose. For the separation process, the mixture (180 mL) was split into 6 portions with each in a separate 40 mL polypropylene centrifuge tube. The dispersion was made up to 40 mL on each centrifuge vial with ethanol.
(b) The extraction of few-layer graphene along with ethyl cellulose was done by centrifugation at a speed of between 5,000 and 14,000 rpm for 15 min leading to collection of graphene with structural feature control and tunable electrical conductivity.
(c) 80% of the supernatant was carefully collected that contains the few-layer graphene particles and ethyl cellulose (henceforth called the 1^{st} batch).
(d) The sediments were refilled with ethanol and vortexed for 1 min, then centrifuged again at 7,500 rpm for 15 min and 80% of supernatant were collected (henceforth called 1^{st} recycled). Repeat the process up to 4 times to get 2^{nd}, 3^{rd}, 4^{th} and 5^{th} recycled graphene particles. In each repetition, the respective sedimentation is first vortexed and then centrifuged before the supernatant is collected.
(e) Furthermore, the collected supernatants were filtered through 5 μm pore sized syringe filter in order to eliminate the large graphene particles and/or unwanted particles, including partially and unexfoliated graphite (>5 μm).

### Step—3. Extraction and Controlled Encapsulation of the Surfactants in Graphene Layers

(a) Extraction of the graphene particles from graphene/ethyl cellulose in ethanol mixtures by flocculation with sodium chloride solution (0.04 g/mL).
(b) Slowly add NaCl solution to the above obtained graphene/ethyl cellulose in ethanol mixtures by keeping a volume ratio of 1:2 between the graphene suspension and NaCl solution. The NaCl solution is prepared by dissolving the NaCl in DI water in the concentration of 40 mg/mL (4 w/v %). Then the mixtures were stirred using magnetic stirring at 200 rpm for 10 minutes for flocculation of graphene/ethyl cellulose particles.
(c) The flocculated graphene/ethyl cellulose particles were subjected to centrifugation by splitting them into six 40 mL polypropylene tubes at a centrifugation speed of 7,500 rpm for 8 minutes.
(d) The centrifuged sediments were washed 3 times in DI water (1 L) to remove NaCl.
(e) The sediments were collected by vacuum filtration in 0.45 μm cellulose ester filter (47 mm diameter).
(f) The filtered samples were detached from the filter membrane and then dried in a hot plate at 50° C. for 6-8 h or by an IR lamp for 3 h. The graphene/ethyl cellulose particles were collected after grinding.
(g) The dried powders were suspended into 300 mL of ethanol and then sonicated for 30 min in ice bath condition. Repeat the process steps 3(b) to 3(f) to allow for the removal of excessive ethyl cellulose, which is encapsulated on to the graphene surface to increase the graphene content in the exfoliated product.

### Step 4. Preparation of Graphene Ink

(a) Mixtures of cyclohexanone and terpineol were prepared with a 85:15 (v/v %) ratio.
(b) 70 mg of the encapsulated graphene particles were added into 1 mL of the above solvent mixtures and the resulting suspension was vortex mixed for 1 min.
(c) The above suspension was subjected to 3 h of bath sonication at room temperature in order to attain uniform dispersion of graphene particles in cyclohexanone/terpineol mixtures.

An optimized process for producing encapsulated graphene particles was performed according to the process described above. The optimized condition for the solvent phase exfoliated (SPE) graphene included an ethyl cellulose weight ratio of 0.5 wt/v %, graphite at 5 wt/v %, a sonication time of 6 h, and a centrifugation speed of 5,000 rpm.

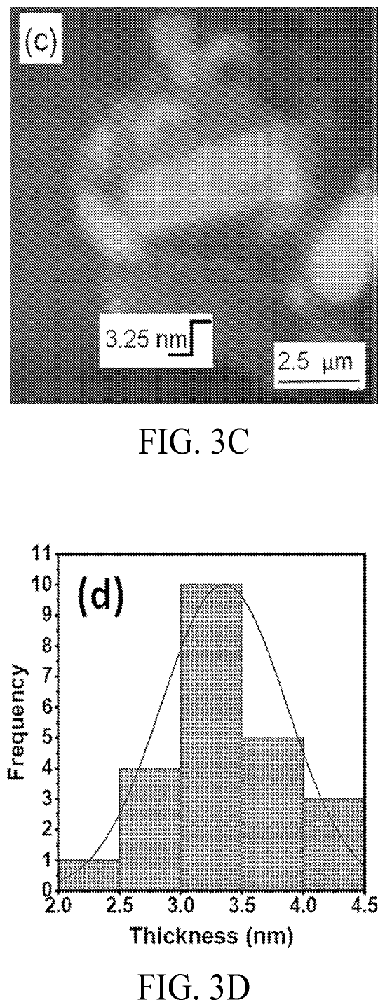

FIGS. 3A and 3B show the transmission electron microscopy (TEM) image and high-resolution TEM (HR-TEM) of SPE individual graphene flakes after removal of the EC surfactants. FIG. 3C shows the thickness of a representative graphene flake using atomic force microscopy (AFM) imaging. FIG. 3D shows a statistical analysis of thickness measurements on 23 flakes, showing the average thickness of graphene flakes is about 10 atomic layers.

1. A method of forming a graphene ink comprising:
forming a mixture comprising graphite powder and an exfoliating agent for the graphite powder dispersed within a liquid dispersant;
adding energy to the mixture thereby causing at least a portion of the graphite powder to exfoliate into few-layered graphene particles comprising less than 20 atomic layers, the exfoliated graphene particles being encapsulated by the exfoliating agent;
separating at least a portion of the encapsulated graphene particles from the mixture; and
dispersing the encapsulated graphene particles within a liquid vehicle system thereby forming the graphene ink.

2. The method of claim 1, wherein the exfoliating agent comprises the exfoliating agent comprises ethyl cellulose, nitrocellulose, carboxymethylcellulose, or mixtures thereof.

3. The method of claim 1, wherein the energy added to the mixture is sonic energy.

4. The method of claim 1, wherein the few-layered graphene particles comprise a quantity of graphene particles having an average thickness of less than 15 atomic layers.

5. The method of claim 1, wherein the few-layered graphene particles comprise a quantity of graphene particles having an average thickness of 10 or fewer atomic layers.

6. The method of claim 1, wherein the separating step comprises extracting the encapsulated graphene particles from the mixture by centrifuging the mixture and recovering a supernatant containing the encapsulated graphene particles, then adding a flocculating agent to the recovered supernatant thereby causing the encapsulated graphene particles to flocculate, and recovering the flocculated graphene particles by filtering.

7. The method of claim 6, wherein the flocculating agent comprises a sodium chloride solution.

8. The method of claim 6, wherein the recovered graphene particles are dried to form a powder comprising the encapsulated graphene particles.

9. An ink composition comprising a quantity of few-layered graphene particles encapsulated within an exfoliating agent.

10. The ink composition of claim 9, wherein the quantity of few-layered graphene particles encapsulated within an exfoliating agent is dispersed in a liquid vehicle system.

11. The ink composition of claim 10, wherein the liquid vehicle system comprises a mixture of one or more ketones and one or more alcohols.

12. The ink composition of claim 11, wherein the liquid vehicle comprises cyclohexanone and terpineol.

13. The ink composition of claim 9, wherein the quantity of few-layered graphene particles has an average thickness of less than 15 atomic layers.

14. The ink composition of claim 9, wherein the quantity of few-layered graphene particles has an average thickness of 10 or fewer atomic layers.

15. The ink composition of claim 9, wherein the quantity of graphene particles is in the form of flakes having a D50 of about 200 nanometers to about 300 nanometers.

16. An electronic or electrochemical device comprising one or more traces printed with the ink according to claim 9.

17. The electronic device of claim 16, wherein the electronic device comprises a phosphate sensor.

18. The electronic device of claim 17, wherein the phosphate sensor comprises an ion selective layer applied over the one or more traces printed with the ink.

19. The electronic device of claim 18, wherein the ion selective layer comprises a cerium acetylacetonate complex.

20. The electronic device of claim 17, wherein the sensor can discriminate between phosphate ions and nitrate ions.
